(19) United States
(12) Patent Application Publication
(10) Pub. No.: US 2025/0391713 A1
(43) Pub. Date: Dec. 25, 2025

(54) DOUBLE-SIDED AIR-CAVITY PACKAGE WITH TOP-SIDE COOLING

(71) Applicant: Qorvo US, Inc., Greensboro, NC (US)

(72) Inventors: Peter Haase, Richardson, TX (US); MD Hasnine, Richardson, TX (US)

(21) Appl. No.: 19/193,024

(22) Filed: Apr. 29, 2025

Related U.S. Application Data
(60) Provisional application No. 63/663,914, filed on Jun. 25, 2024.

(51) Int. Cl. H01L 23/047; H01L 21/48; H01L 21/56; H01L 23/00; H01L 23/08; H01L 23/367; H01L 23/538; H01L 25/065; H01L 25/10

(52) U.S. Cl. CPC H01L 23/047; H01L 21/4871; H01L 21/4875; H01L 21/565; H01L 23/08; H01L 23/3677; H01L 23/5386; H01L 24/16; H01L 24/32; H01L 24/48; H01L 24/73; H01L 25/0655; H01L 25/105; H01L 2224/16245; H01L 2224/32245; H01L 2224/48245; H01L 2224/48464; H01L 2224/73265; H01L 2924/16152; H01L 2924/16251

(57) ABSTRACT

The present disclosure relates to a double-sided air-cavity package that includes a metalized laminate structure with a heat spreader, a perimeter structure protruding from a periphery of a bottom surface of the metalized laminate structure without covering the heat spreader, a lid positioned parallel to the metalized laminate structure and bonded to the perimeter structure, a first electronic component, and a second electronic component. Herein, a combination of the metalized laminate structure, the perimeter structure, and the lid delimits a closed air cavity. The first electronic component is attached to the bottom surface of the metalized laminate structure proximate to the heat spreader, positioned within the air cavity, and electrically connected to at least one interior conductive element within the perimeter structure. The second electronic component is attached to a top surface of the metalized laminate structure, positioned outside the air cavity, and does not reside over the heat spreader.

### RELATED APPLICATIONS

This application claims the benefit of provisional patent application Ser. No. 63/663,914, filed Jun. 25, 2024, the disclosure of which is hereby incorporated herein by reference in its entirety.

### FIELD OF THE DISCLOSURE

The present disclosure relates to a double-sided air-cavity package with an efficient path for top-side cooling and a process for making the same.

### BACKGROUND

With the popularity of portable electronic products in both consumer and military applications, such as smart phones, tablet computers, and so forth, double-sided packages are becoming more and more attractive in microelectronics devices to achieve electronics densification with a small footprint.

In semiconductor packaging, mold compounds are normally used to encapsulate electronic components (e.g., flip-chip dies, wire-bonding dies, and surface mounted devices) to protect the electronic components against damage from the outside environment. However, direct contact between the mold compounds and active component surfaces may adversely impact their electrical performance, especially for radio frequency (RF) electronic components. Accordingly, it is desirable to package the RF electronic components in a configuration that is more appropriate for high frequency performance. An air-cavity packaging technique is a desired option, in which dry air provides a considerably lower dielectric constant than typical mold compounds, thus reducing losses and providing improved electrical performance at high frequencies.

On the other hand, as the operating speed of the RF electronic components increases, concentrated heat flux in active regions of some RF electronic components (e.g., gallium nitride devices) significantly increases. Effectively managing component heating and controlling junction temperatures becomes essential, given their potential to negatively impact performance and reliability. In the case of the high-power RF electronic components attached to a package substrate, the ability to dissipate large amounts of heat through the package substrate underneath the electronic components (bottom-side cooling) is limited. This limitation results in high thermal resistance, ultimately degrading the electrical component's lifetime. In addition, depending solely on heat sinks attached to the package substrate has been proven insufficient for dissipating a highly concentrated heat flux.

Accordingly, there remains a need for improved packaging designs, which utilize double-sided configurations for attaining small footprints and air-cavity configurations for reduced losses and enhanced electrical performance. Additionally, there is also a need for providing efficient paths for heat dissipation of the high-power/high frequency electronic components.

### SUMMARY

The present disclosure relates to a double-sided air-cavity package with top-side cooling and a process for making the same. The disclosed package includes a metalized laminate structure with a heat spreader, a perimeter structure, a lid, a first electronic component, and a second electronic component. Herein, the perimeter structure that includes at least one interior conductive element protrudes from a first surface of the metalized laminate structure and is positioned at a periphery of the metalized laminate structure without covering any portion of the heat spreader. The lid is positioned parallel to the metalized laminate structure and bonded to the perimeter structure, such that a combination of the metalized laminate structure, the perimeter structure, and the lid delimits a closed air cavity. The first electronic component is attached to the first surface of the metalized laminate structure proximate to the heat spreader and positioned within the air cavity, such that heat generated by the first electronic component is capable of being dissipated through the heat spreader in the metalized laminate structure. In addition, the first electronic component is electrically connected to the at least one interior conductive element within the perimeter structure. The second electronic component is attached to a second surface of the metalized laminate structure opposite the first surface of the metalized laminate structure. The second electronic component is positioned outside the air cavity and does not reside over the heat spreader.

In one embodiment of the double-sided air-cavity package, the metalized laminate structure further includes a laminate body and a number of routing conductors inside the laminate body. The heat spreader is embedded in and extends vertically through the laminate body, such that a first surface of the heat spreader is a part of the first surface of the metalized laminate structure. The first electronic component is electrically connected to the at least one interior conductive element via certain ones of the routing conductors.

In one embodiment of the double-sided air-cavity package, the first electronic component is a wire-bond die. The first electronic component is attached to the first surface of the heat spreader via a die attach material, and wire bonds of the first electronic component are coupled to the certain ones of the routing conductors in the metalized laminate structure.

According to one embodiment, the double-sided air-cavity package further includes a top mold compound. The top mold compound is applied to the second surface of the metalized laminate structure to at least partially encapsulate the second electronic component.

According to one embodiment, the double-sided air-cavity package further includes a thermal interposer. The thermal interposer is attached to a second surface of the heat spreader, opposite the first surface of the heat spreader, via an interposer attach material. The thermal interposer extends vertically through the top mold compound, such that the heat generated by the first electronic component is capable of being dissipated through the heat spreader within the metalized laminate structure and the thermal interposer embedded in the top mold compound.

In one embodiment of the double-sided air-cavity package, the second electronic component is a flip-chip die or a surface mounted device (SMD).

In one embodiment of the double-sided air-cavity package, the lid is formed from FR4 or liquid crystal polymer (LCP).

In one embodiment of the double-sided air-cavity package, the perimeter structure includes a mold wall and the at least one interior conductive element. The mold wall protrudes from the first surface of the metalized laminate structure and is positioned at the periphery of the metalized laminate structure. The at least one interior conductive element is embedded in the mold wall and extends vertically through the mold wall, such that a top side and a bottom side of the at least one interior conductive element are not covered by the mold wall.

In one embodiment of the double-sided air-cavity package, the mold wall is shaped to provide a recess, which is located at an internal side of the mold wall and vertically away from the metalized laminate structure, so as to accommodate the lid. The lid fits into the recess and is bonded to the mold wall via a lid attach material.

In one embodiment of the double-sided air-cavity package, the at least one interior conductive element includes a number of interior conductive elements, each of which is a metal post. A top side and a bottom side of each interior conductive element are not covered by the mold wall. Herein the top side of each interior conductive element is electrically coupled to a corresponding one of the routing conductors in the metalized laminate structure.

According to one embodiment, the double-sided air-cavity package further includes a number of plating sections. Herein, each plating section is directly formed underneath the bottom side of a corresponding interior conductive element. Each plating section includes nickel, gold, and/or palladium.

In one embodiment of the double-sided air-cavity package, the at least one interior conductive element is a stilted interconnect, which includes a dielectric region and multiple conductive pillars. The dielectric region is formed of an insulating material or a semi-insulating material. Each conductive pillar extends vertically through the dielectric region, such that a top side and a bottom side of each conductive pillar are not covered by the dielectric region or the mold wall. The top side of each conductive pillar is electrically coupled via a solder paste to a corresponding routing conductor in the metalized laminate structure. Each conductive pillar is composed of alternating plated vias and metal plates or alternating coined inserts and metal plates.

In one embodiment of the double-sided air-cavity package, the at least one interior conductive element includes one continuous stilted interconnect having an open or closed ring frame shape.

In one embodiment of the double-sided air-cavity package, the at least one interior conductive element includes a number of discrete stilted interconnects, each of which has a column shape.

According to one embodiment, the double-sided air-cavity package further includes a number of electrical contacts. Herein, each electrical contact is directly formed underneath the bottom side of a corresponding conductive pillar and is formed from solder balls or solder paste.

According to one embodiment, a communication device includes a control system, a baseband processor, receive circuitry, and transmit circuitry. Herein, at least one or any combination of the control system, the baseband processer, the transmit circuitry, and the receive circuitry is implemented in a double-sided air-cavity package, which includes a metalized laminate structure with a heat spreader, a perimeter structure, a lid, a first electronic component, and a second electronic component. Herein, the perimeter structure that includes at least one interior conductive element protrudes from a first surface of the metalized laminate structure and is positioned at a periphery of the metalized laminate structure without covering any portion of the heat spreader. The lid is positioned parallel to the metalized laminate structure and bonded to the perimeter structure, such that a combination of the metalized laminate structure, the perimeter structure, and the lid delimits a closed air cavity. The first electronic component is attached to the first surface of the metalized laminate structure proximate to the heat spreader and positioned within the air cavity, such that heat generated by the first electronic component is capable of being dissipated through the heat spreader in the metalized laminate structure. In addition, the first electronic component is electrically connected to the at least one interior conductive element within the perimeter structure. The second electronic component is attached to a second surface of the metalized laminate structure opposite the first surface of the metalized laminate structure. The second electronic component is positioned outside the air cavity and does not reside over the heat spreader.

According to one embodiment, a method of fabricating a double-sided air-cavity package starts with forming a perimeter structure on a first surface of a metalized laminate structure. Herein, the metalized laminate structure includes a heat spreader, while the perimeter structure includes a mold wall and at least one interior conductive element. The mold wall protrudes from a periphery of the first surface of the metalized laminate structure without covering any portion of the heat spreader, and is shaped to provide a recess at an internal side and vertically away from the metalized laminate structure. The at least one interior conductive element is embedded in the mold wall. Next, a first electronic component is attached to the first surface of the metalized laminate structure proximate to the heat spreader. The first electronic component is electrically connected to the at least one interior conductive element within the perimeter structure. A lid is then placed and bonded to the recess of the mold wall to be parallel to the metalized laminate structure. As such, a combination of the metalized laminate structure, the perimeter structure, and the lid delimits a closed air cavity, within which the first electronic component is located. A second electronic component is attached to a second surface of the metalized laminate structure opposite the first surface of the metalized laminate structure. The second electronic component is positioned outside the air cavity and does not reside over the heat spreader.

In one embodiment of the method, the metalized laminate structure further includes a laminate body and a number of routing conductors inside the laminate body. The heat spreader is embedded in and extends vertically through the laminate body. The first electronic component is electrically connected to the at least one interior conductive element via certain ones of the routing conductors.

In one embodiment of the method, the first electronic component is a wire-bond die, and wire bonds of the first electronic component are coupled to the certain ones of the routing conductors in the metalized laminate structure. The first electronic component is attached to a first surface of the heat spreader via a die attach material.

According to one embodiment, the method further includes attaching a thermal interposer to a second surface of the heat spreader opposite the first surface of the heat spreader. Herein, the second surface of the heat spreader is a part of the second surface of the metalized laminate structure. Next, a top mold compound is applied to the second surface of the metalized laminate structure to completely encapsulate the second electronic component and the thermal interposer. The top mold compound is then thinned down until a backside of the thermal interpose is exposed.

In one embodiment of the method, the at least one interior conductive element includes a number of interior conductive elements, each of which is a metal post.

According to one embodiment, the method further includes, after placing and bonding the lid, co-grinding the perimeter structure and the lid until a second side of each interior conductive element opposite the first side of each interior conductive element is exposed though the mold wall. Next, the exposed bottom side of each interior conductive element is plated by electroless nickel electroless palladium immersion gold (ENEPIG) plating or electroless nickel immersion gold (ENIG) plating.

In one embodiment of the method, the at least one interior conductive element is a stilted interconnect, which includes a dielectric region and multiple conductive pillars. The dielectric region is formed of an insulating material or a semi-insulating material. Each conductive pillar extends vertically through the dielectric region, and is composed of alternating plated vias and metal plates or alternating coined inserts and metal plates.

In one embodiment of the method, forming the perimeter structure starts with attaching the at least one interior conductive element to the first surface of the metalized laminate structure. Herein, a first side of each conductive pillar in the at least one interior conductive element is electrically coupled via a solder paste to a corresponding routing conductor in the metalized laminate structure. And then, a first mold compound is selectively applied to the first surface of the metalized laminate structure to form the mold wall that completely encapsulates the at least one interior conductive element, and to provide the perimeter structure.

According to one embodiment, the method further includes, after placing and bonding the lid, co-grinding the perimeter structure and the lid until a second side of each of the conductive pillars opposite the first side of each of the conductive pillars is exposed though the dielectric region and the mold wall. Next, a solder ball is applied to the exposed second side of each of the conductive pillars. The solder ball is reflowed to provide an electrical contact at the second side of each of the conductive pillars.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a conventional air-cavity package.

FIGS. 2A-2B illustrate an exemplary double-sided air-cavity package according to aspects of the present disclosure.

FIG. 3 is a flowchart showing a fabricating process for making the double-sided air-cavity package shown in FIG. 2A.

FIGS. 4A-4L illustrate steps associated with the fabricating process provided in FIG. 3.

FIG. 5 is a flowchart showing a process for making the double-sided air-cavity package shown in FIG. 2B.

FIGS. 6A-6J illustrate steps associated with the fabricating process provided in FIG. 5.

FIG. 7 illustrates a block diagram of a communication device, which may include the double-sided air-cavity package illustrated in FIGS. 2A-2B according to some embodiments of the present disclosure.

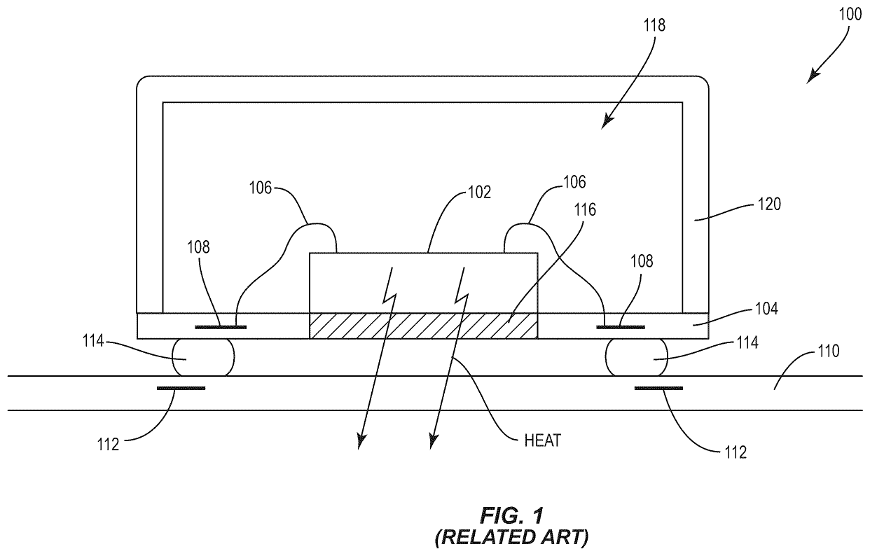

It will be understood that for clarity of illustration, FIGS. 1-7 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Additionally, to the extent that the term “approximately” or “substantially” is used in the claims, it is herein defined to be within five percent (5%).

Aspects disclosed in the detailed description include a double-sided air-cavity package with top-side cooling and a process for making the same. In particular, an air-cavity is delimited by a metalized laminate structure, a perimeter structure with interior conductive elements protruding from a first side of the metalized laminate structure, and a lid positioned parallel to the metalized laminate structure and bonded to the perimeter structure. The metalized laminate structure has signal routing conductors that couple to the interior conductive elements of the perimeter structure. The metalized laminate structure may also include a heat spreader. One or more high frequency/high power dies or components are placed at the first side of the metalized laminate structure over the heat spreader and within the air-cavity, while one or more dies or components are placed at a second side of the metalized laminate structure and outside the air-cavity. The interior conductive elements of the perimeter structure are exposed so that they may be configured to couple to a board or the like for integration into an electronic device.

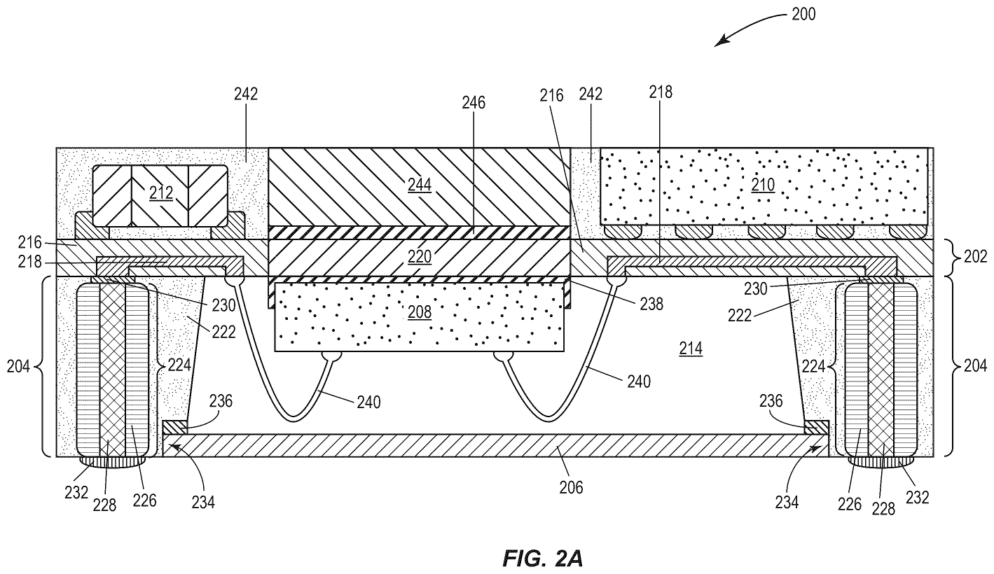

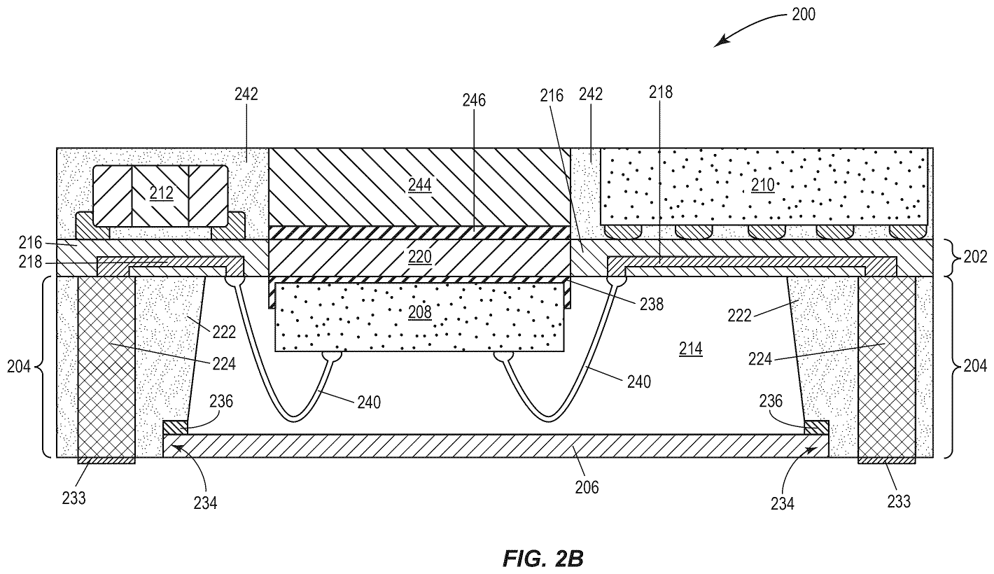

Before addressing aspects of the present disclosure, a brief overview of how heat may be trapped near a heat-producing die is provided with reference to FIG. 1. A discussion of aspects of the present disclosure that provide improved designs to remove heat from die proximity begins below with reference to FIG. 2. FIG. 1 illustrates a conventional air-cavity package 100, in which a wire-bond die 102 is placed on a top surface of a metalized laminate structure 104. Wire bonds 106 may couple internal circuitry of the wire-bond die 102 to conductors 108 in the metalized laminate structure 104. Typically, the metalized laminate structure 104 is mounted on another laminate 110 that also has conductors 112, such as a printed circuit board (PCB) made from FR4 or other similar materials, through a conductive material such as solder balls or simply solder 114. Since the solder balls 114 are relatively short, it is difficult to accommodate dies or components (especially large surface mounted components) on a bottom surface of the metalized laminate structure 104 to build a double-sided configuration.

It is possible that the metalized laminate structure 104 is also made with FR4, although more commonly, there may be a heat slug 116 in the metalized laminate structure 104. In contrast to the metal heat slug 116, FR4, in particular, has poor thermal conductivity. Accordingly, heat generated in the wire-bond die 102 may travel into the metalized laminate structure 104 and the laminate 110 and remain relatively confined proximate to the wire-bond die 102. Such heat buildup may result in changes in the operation of the circuits within the wire-bond die 102 and, in extreme cases, may damage the circuits such that they are inoperable. This trapped heat is exacerbated when the wire-bond die 102 is encapsulated within an air cavity 118 delimited by an over-structure 120 formed typically from a mold compound or when the wire-bond die 102 is directly encapsulated by the mold compound without any air-cavity (not shown). The use of the air cavity 118 is desirable for certain radio frequency (RF) applications where the dielectric property of air compared to the mold compound may give performance advantages.

FIGS. 2A and 2B illustrate an exemplary double-sided air-cavity package 200 with top-side cooling according to some embodiments of the present disclosure. For the purpose of this illustration, the double-sided air-cavity package 200 includes a metalized laminate structure 202, a perimeter structure 204, a lid 206, a wire-bond die 208, a flip-chip die 210, and a surface mounted device (SMD) 212. Herein, the perimeter structure 204 protrudes from a periphery of a first surface (e.g., a bottom surface) of the metalized laminate structure 202, while the lid 206 is positioned parallel to the metalized laminate structure 202 and bonded to the perimeter structure 204 to delimit a closed air-cavity 214 (vertically between the first surface of the metalized laminate structure 202 and the lid 206 and surrounded by the perimeter structure 204). The wire-bond die 208 is attached to the first surface of the metalized laminate structure 202, while the flip-chip die 210 and the SMD 212 are mounted on a second surface (e.g., a top surface) of the metalized laminate structure 202 opposite the first surface of the metalized laminate structure 202. In different applications, the double-sided air-cavity package 200 may include more electronic components with different component types (e.g., wire-bond dies, flip chip dies, SMDs, passive components) attached to the first surface of the metalized laminate structure 202, and may include fewer or more electronic components with different component types (e.g., wire-bond dies, flip chip dies, SMDs, passive components) attached to the second surface of the metalized laminate structure 202.

In detail, the metalized laminate structure 202 includes a laminate body 216, multiple routing conductors 218 inside the laminate body 216 (for simplicity and clarity, only two routing conductors are shown herein), and a heat spreader 220 embedded in and extending vertically through the laminate body 216 (extending vertically from the first surface of the metalized laminate structure 202 to the second surface of the metalized laminate structure 202). The laminate body 216 may be formed from FR4 or other similar materials. The routing conductors 218 may be formed from copper or other metal materials, which are capable of transmitting electrical signals as well as heat. The heat spreader 220 is a thermally conductive structure, which may have at least 100 W/m·k thermal conductivity and may be formed from copper or other thermally conductive materials.

The perimeter structure 204 includes a mold wall 222 and one or more interior conductive elements 224 within the mold wall 222. The mold wall 222 protrudes from the periphery of the first surface of the metalized laminate structure (i.e., a periphery of a first surface of the laminate body 216). The mold wall 222 may be formed from an organic epoxy resin system or the like. Each interior conductive element 224 is embedded in the mold wall 222 and extends vertically through the mold wall 222 (e.g., from a top surface of the mold wall 222 to a bottom surface of the mold wall 222, such that a top side and a bottom side of each interior conductive element 224 are not covered by the mold wall 222).

In different applications, the one or more interior conductive elements 224 may be implemented differently. As shown in FIG. 2A, each interior conductive element 224 may be a stilted interconnect, which includes a dielectric region 226 and multiple conductive pillars 228 extending vertically through the dielectric region 226. Herein, the one or more interior conductive elements 224 may be a continuous stilted interconnect having an open/closed ring frame shape, or include multiple discrete stilted interconnects, each of which may have a column shape. The dielectric region 226 may be formed of an insulating material (e.g., FR4, polyimide, etc.) or a semi-insulating material (e.g., semi-insulating gallium arsenide, semi-insulating silicon carbide, etc.). Each conductive pillar 228 may be composed of alternating multiple plated vias and metal plates or alternating multiple coined inserts and metal plates (not shown). In some cases, each interior conductive element 224 may be a metal post (e.g., a copper post, a silver post, a gold post, or the like) that is directly embedded in and extends vertically through the mold wall 222, as illustrated in FIG. 2B.

If each interior conductive element 224 is one stilted interconnect, the one or more interior conductive elements 224 may be coupled to certain ones of the routing conductors 218 of the metalized laminate structure 202 via a solder paste 230 or flux printing (FIG. 2A). In addition, electrical contacts 232, which may be formed from solder balls or solder paste, are provided directly underneath each interior conductive element 224 for further package assembly (e.g., mounting to a PCB, not shown). If each interior conductive element 224 is one metal post, the one or more interior conductive elements 224 may be directly coupled to the certain ones of the routing conductors 218 of the metalized laminate structure 202 (FIG. 2B). In addition, a bottom side of the metal post 224 is plated to provide a plating section 233 for further package assembly (e.g., mounting to a PCB). The plating section 233 includes nickel and gold/palladium.

Furthermore, the mold wall 222 is shaped to provide a recess 234 (also referred to as a shoulder or lip) at a lower internal side (i.e., an internal side away from the metalized laminate structure 202), so as to accommodate the lid 206. The lid 206 fits into the recess 234 of the mold wall 222, such that a combination of the metalized laminate structure 202, the perimeter structure 204, and the lid 206 delimits the closed air cavity 214. In one embodiment, the lid 206 is bonded to the recess 234 via a lid attach material 236, which may be an epoxy. The lid 206 may be formed from FR4 or liquid crystal polymer (LCP).

The wire-bond die 208 may be a high frequency/high power die (e.g., an RF power amplifier) and is positioned inside the closed air cavity 214. The wire-bond die 208 is attached to the first surface of the metalized laminate structure 202 via a die attach material 238 proximate to the heat spreader 220. In one embodiment, the wire-bond die 208 may be attached to a first surface of the heat spreader 220 (the first surface of the heat spreader 220 is a portion of the first surface of the metalized laminate structure 202) via the die attach material 238 (e.g., epoxy). As such, heat generated by the wire-bond die 208 can be dissipated upward. Wire bonds 240 of the wire-bond die 208 are coupled to certain ones of the routing conductors 218 of the metalized laminate structure 202. As such, electrical signals may be transmitted between the wire-bond die 208 to external circuitry (not shown) through the wire bonds 240, the routing conductors 218 in the metalized laminate structure 202, and the interior conductive elements 224 inside the perimeter structure 204.

The flip-chip die 210 and the SMD 212 are attached to the second surface of the metalized laminate structure 202 (e.g., via solder balls or solder paste), and are electrically coupled to the routing conductors 218 in the metalized laminate structure 202. As such, the flip-chip die 210 and the SMD 212 are capable of communicating with each other, with the wire-bond die 208, and/or with external circuitry (via the routing conductors 218 and the interior conductive elements 224, not shown). Careful placement of the flip-chip die 210, the SMD 212, and the wire-bond die 208 allows for optimized signal paths, which may have reduced interconnect lengths and a potential for better matching and filtering characteristics.

In some applications, the double-sided air-cavity package 200 may further include a top mold compound 242 formed over the second surface of the metalized laminate structure 202 to at least partially encapsulate the flip-chip die 210 and the SMD 212. The top mold compound 242 may be formed from an organic epoxy resin system or the like. As illustrated in FIGS. 2A and 2B, the top mold compound 242 encapsulates sides of the flip-chip die 210 and underfills the bottom of the flip-chip die 210, while a backside of the flip-chip die 210 is exposed. In addition, the top mold compound 242 fully encapsulates the SMD 212. If the heat spreader 220 is present in the metalized laminate structure 202, there is a thermal interposer 244 aligned with the heat spreader 220 and extending vertically through the top mold compound 242. The thermal interposer 244 may be attached to a second surface of the heat spreader 220 (the second surface of the heat spreader 220 is a portion of the second surface of the metalized laminate structure 202) via an interposer attach material 246 (e.g., epoxy). As such the heat generated by the wire-bond die 208 can be dissipated upward through the heat spreader 220 within the metalized laminate structure 202 and the thermal interposer 244 embedded in the top mold compound 242. Herein, a top surface of the thermal interposer 244 and the backside of the flip-chip die 210 are exposed through the top mold compound 242 and may be thermally coupled to an external heat dissipating element (e.g., an external heat sink, not shown). The thermal interposer 244 may be a copper slug or a molybdenum copper slug.

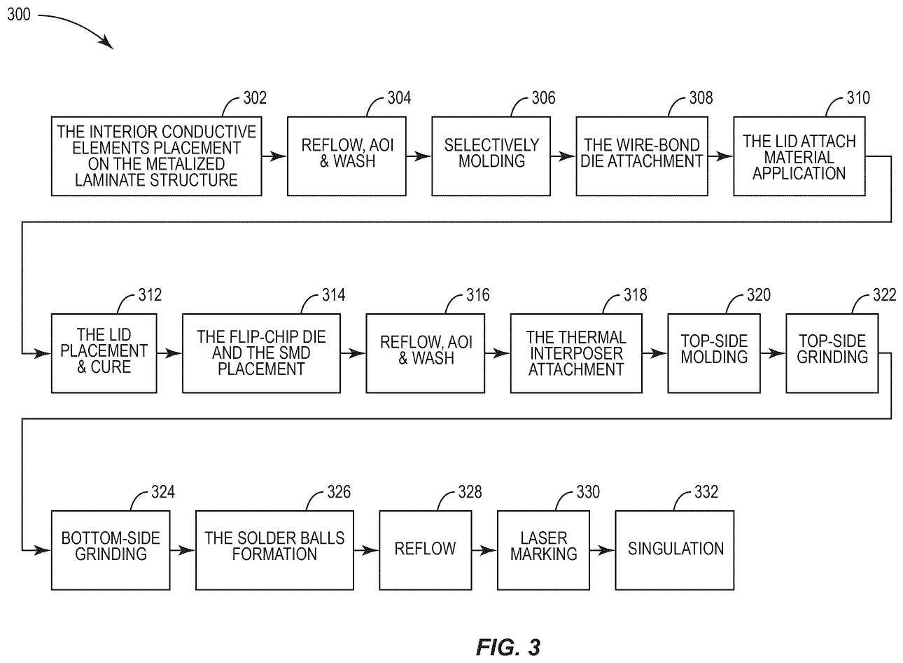

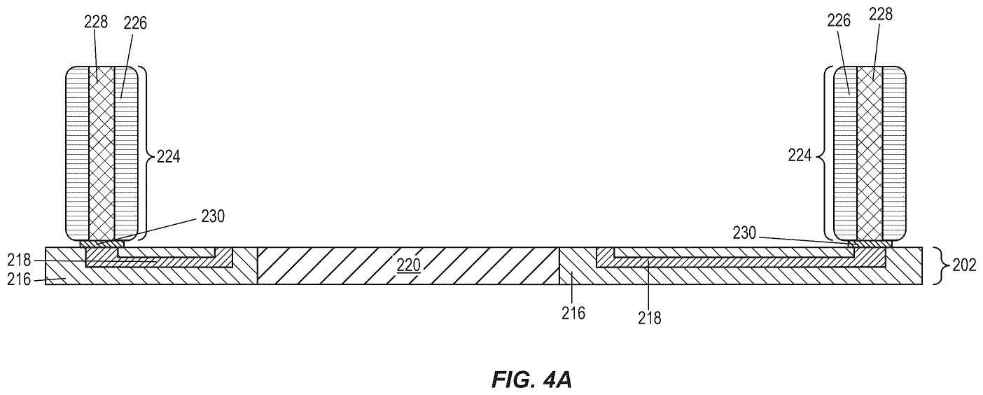

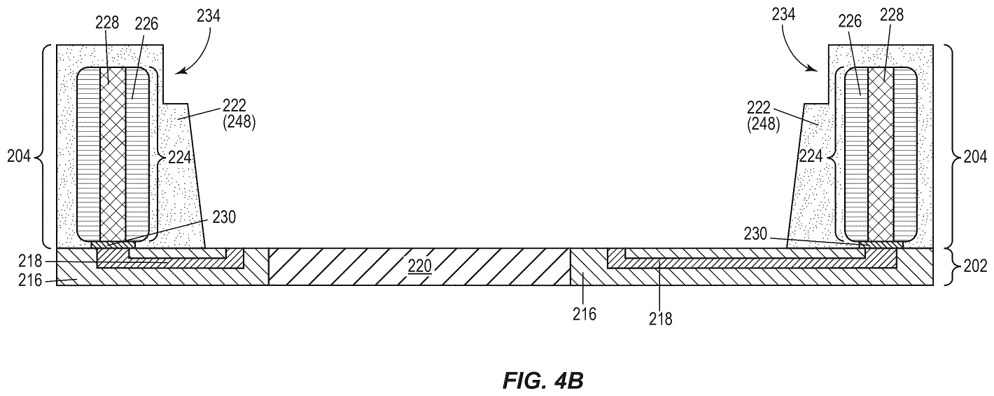

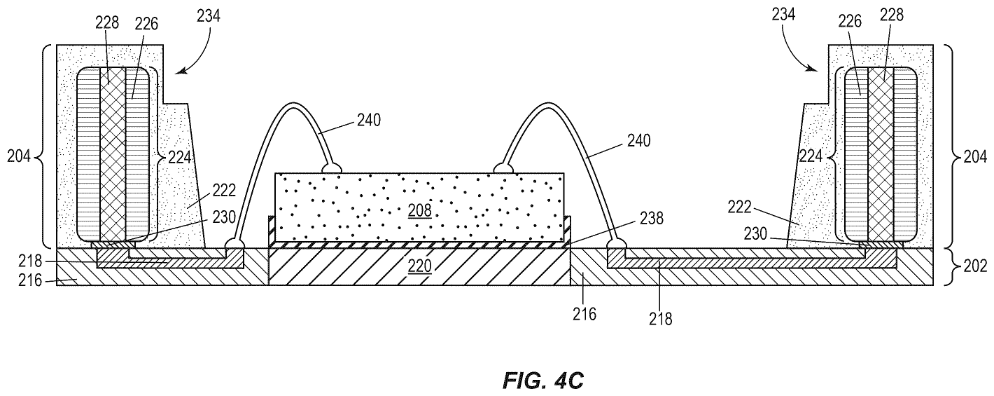

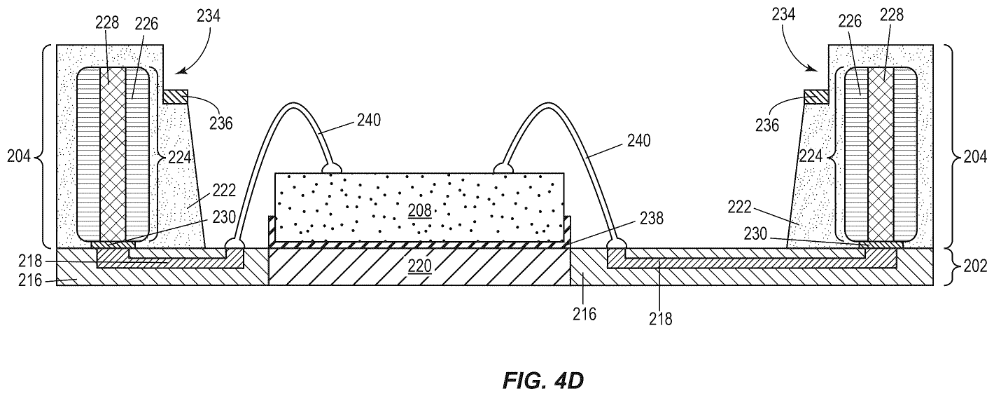

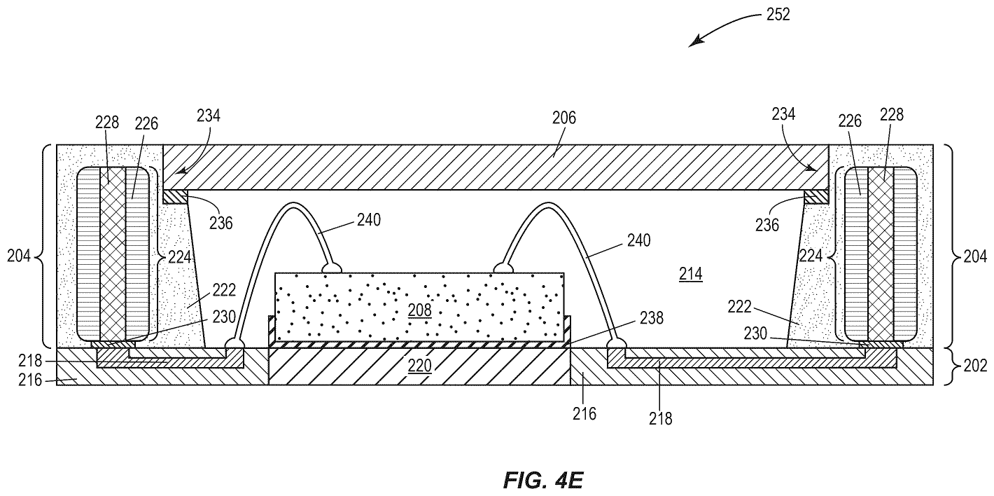

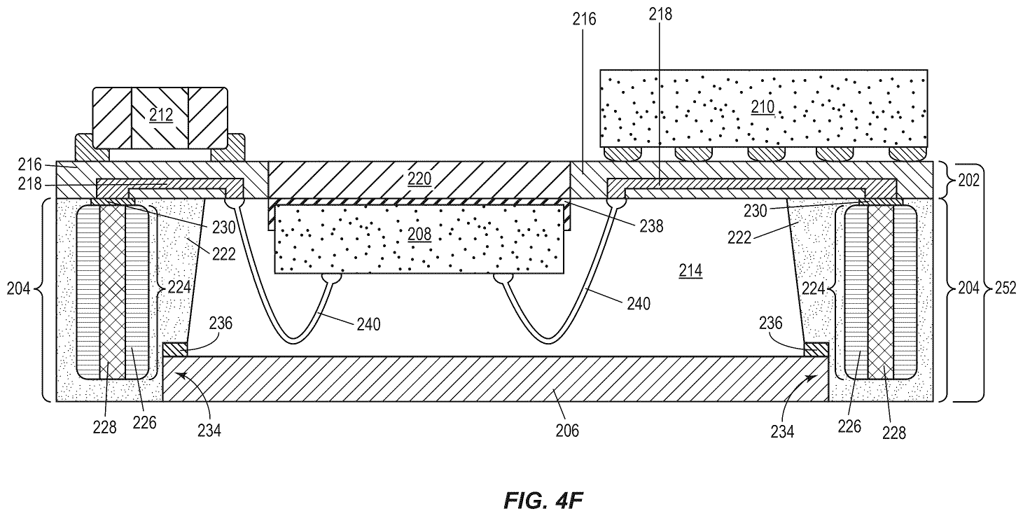

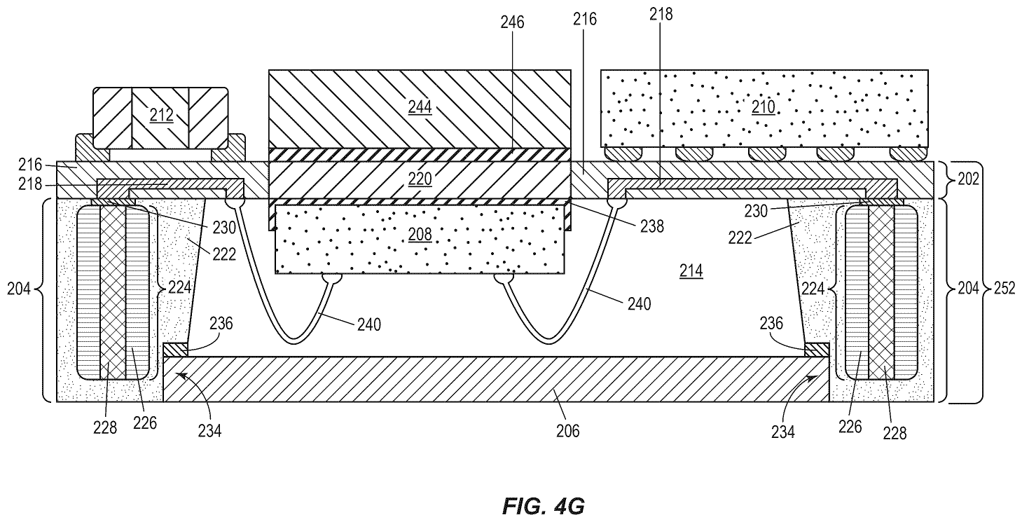

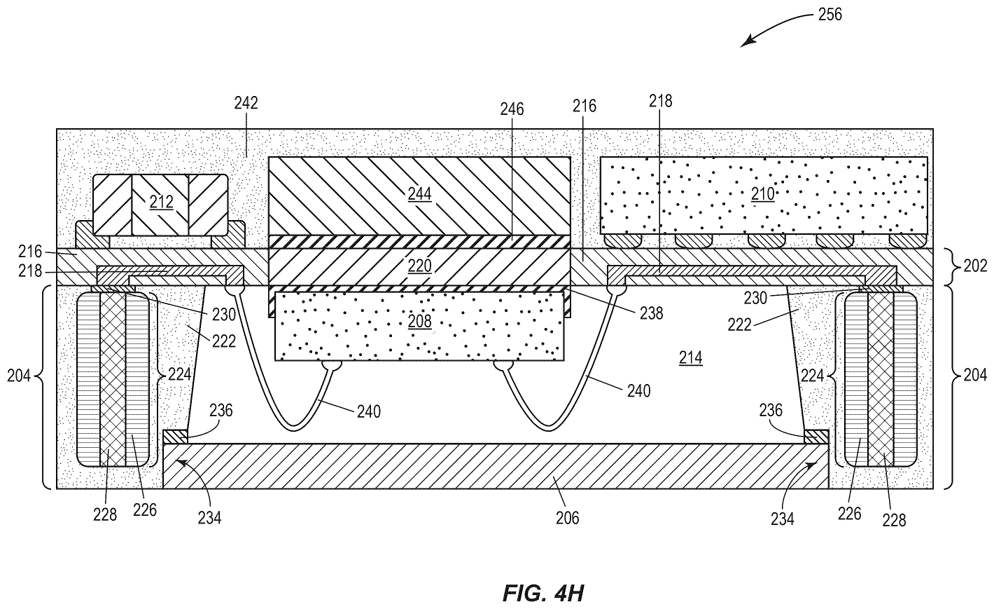

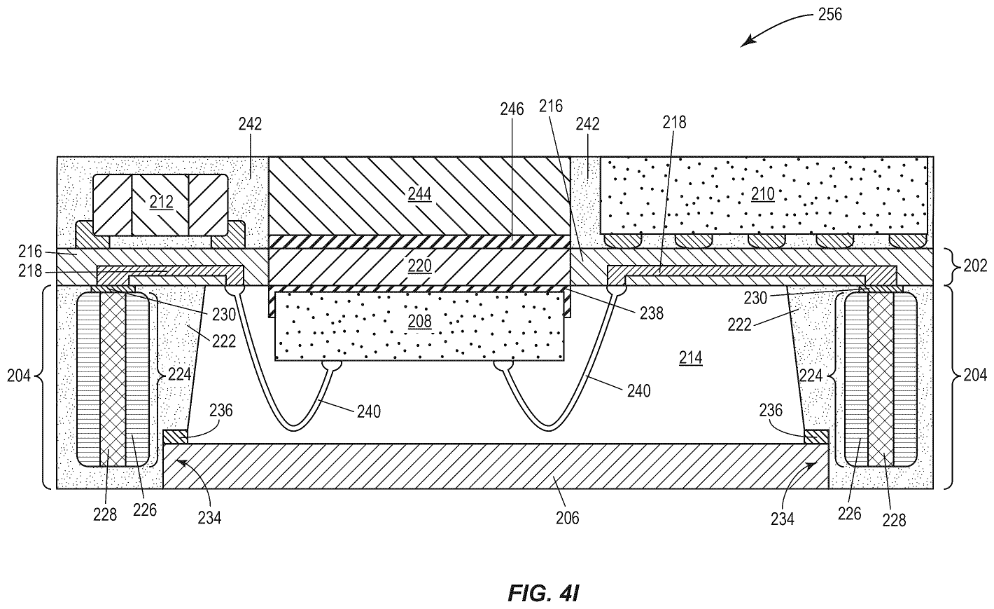

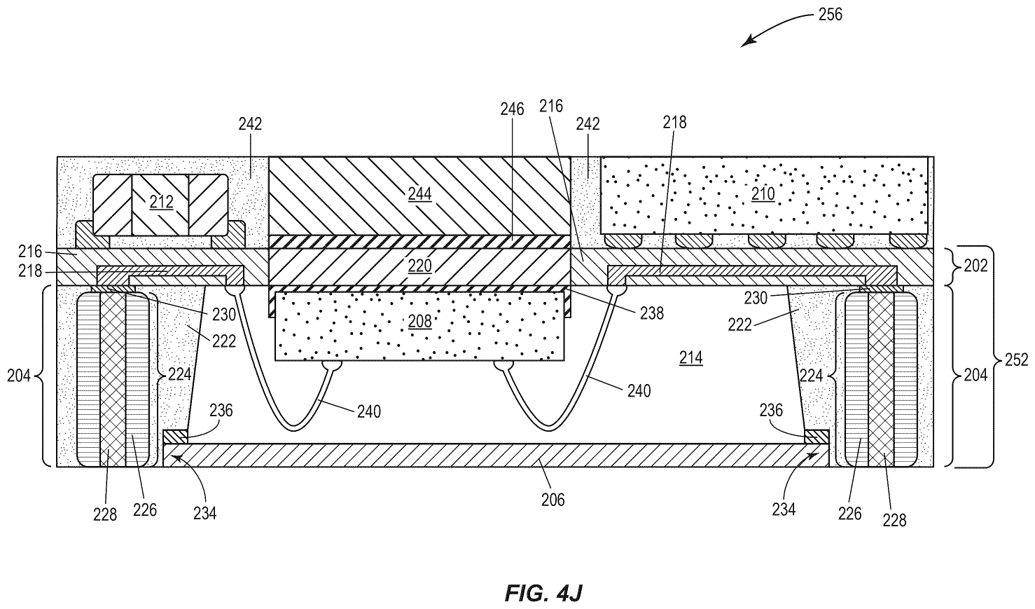

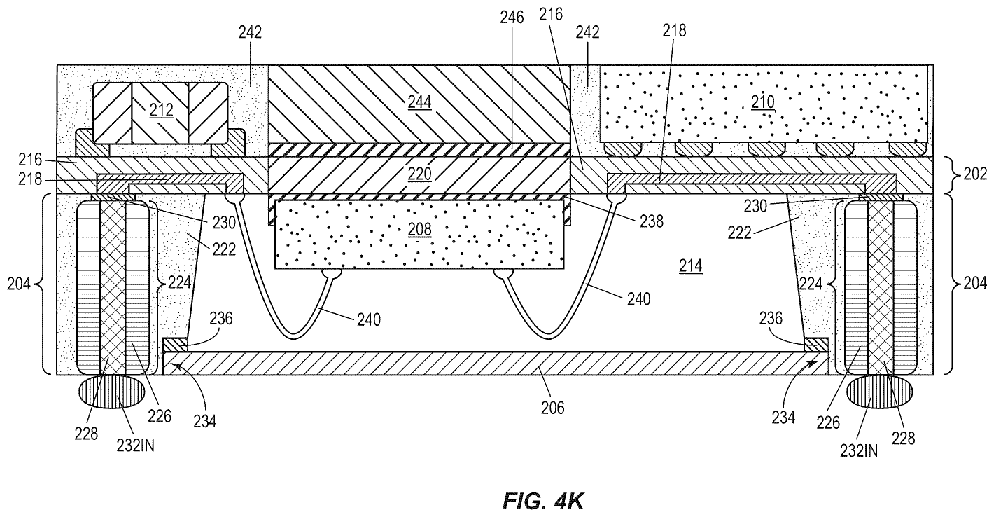

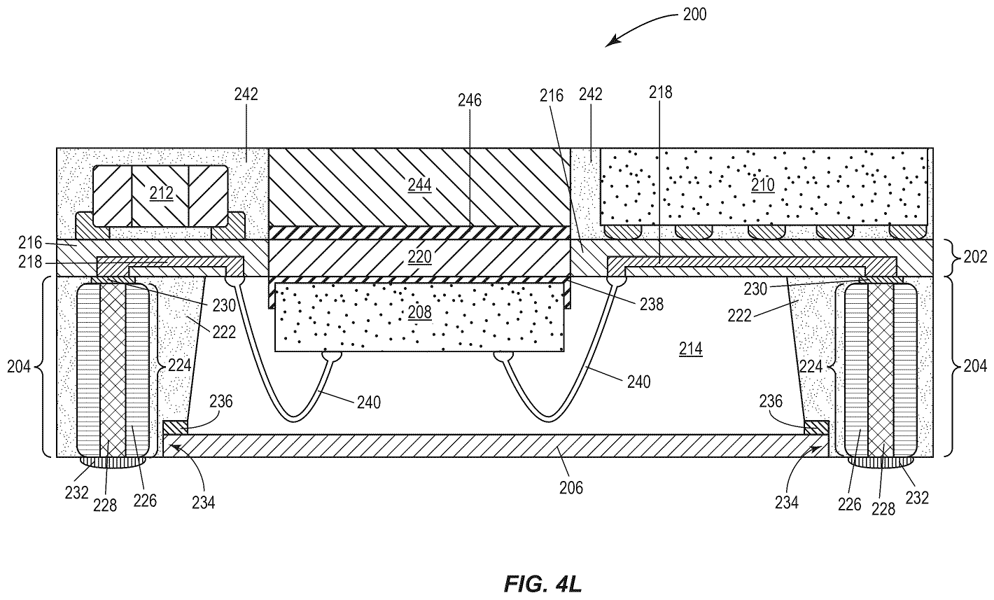

FIG. 3 provides a flow diagram that illustrates an exemplary process 300 for fabricating the double-sided air-cavity package 200 shown in FIG. 2A according to some embodiments of the present disclosure. FIGS. 4A-4L illustrate the steps associated with the fabricating process 300 provided in FIG. 3. Although the flow diagram and the associated steps are illustrated in a series, they are not necessarily order dependent. Some steps may be done in a different order than that presented. Further, processes within the scope of this disclosure may include fewer or more steps than those illustrated in FIG. 3 and FIGS. 4A-4L.

In this regard, the process 300 starts with placing the one or more interior conductive elements 224, each of which includes the dielectric region 226 and the conductive pillars 228, on the first surface of the metalized laminate structure 202 (step 302), as illustrated in FIG. 4A. Herein, the one or more interior conductive elements 224 are coupled to the metalized laminate structure 202 via the solder paste 230 or flux printing, and each conductive pillar 228 within the one or more interior conductive elements 224 is electrically and thermally connected to a corresponding routing conductor 218 within the metalized laminate structure 202. For the purpose of this illustration, the metalized laminate structure 202 includes one heat spreader 220, which extends vertically through the laminate body 216 and is surrounded by the one or more interior conductive elements 224 (i.e., the heat spreader 220 does not extend horizontally underneath any portion of the one or more interior conductive elements 224). In different applications, the metalized laminate structure 202 may include more heat spreaders extending vertically through the laminate body 216 and surrounded by the one or more interior conductive elements 224. The process 300 continues by using a reflow, automated optical inspection (AOI), and wash (step 304, not shown) to clean any undesired solder paste residue or flux residue.

Next, a mold compound 248 is applied over the first surface of the metalized laminate structure 202 to provide the mold wall 222 at the periphery of the metalized laminate structure 202 (step 306), as illustrated in FIG. 4B. The mold wall 222 completely encapsulates each interior conductive element 224 without covering a center portion of the first surface of the metalized laminate structure 202 (i.e., the first surface of the heat spreader 220 is completely exposed through the mold wall 222). In addition, the mold wall 222 is formed to include the recess 234 (also referred to as a shoulder or lip) at an upper internal side of the mold wall 222. Note that the “lower” and “upper” location references are interchangeable, as an intermediate structure(s) may be flipped upside down during the fabrication process. Herein, a combination of the mold wall 222 and the one or more interior conductive elements 224 constitutes the perimeter structure 204. The mold wall 222 may be formed by a selective molding process.

The wire-bond die 208 is attached to the first surface of the heat spreader 220 of the metalized laminate structure 202 via the die attach material 238 (step 308), as illustrated in FIG. 4C. As such, the heat generated by the wire-bond die 208 can be dissipated through the heat spreader 220 of the metalized laminate structure 202. As illustrated, the die attach material 238 is co-extensive with the heat spreader 220 but does not have to be. Likewise, it is possible that the die attach material 238 spills past edges of the heat spreader 220. However, a maximal heat transfer suggests that the heat spreader 220 be at least as large as the die attach material 238. The wire bonds 240 of the wire-bond die 208 are coupled to the certain ones of the routing conductors 218 of the metalized laminate structure 202, such that electrical signals can be transmitted from or into the wire-bond die 208 through the wire bonds 240, the routing conductors 218, and the interior conductive elements 224 connected to the routing conductors 218. During this attaching step, a curing procedure may be utilized to solidate the die attach material 238, and the curing procedure depends on the nature of the epoxy used for the die attach material 238 (e.g., infrared curing, ultraviolet curing, heat curing, or the like). In addition, after the attachment of the wire-bond die 208, a plasma cleaning may be followed.

Before placing the lid 206 into the recess 234 of the perimeter structure 204, the lid attach material 236 (e.g., epoxy) is dispended at a lower surface of the recess 234 (step 310), as illustrated in FIG. 4D. The lid 206 is then placed into the perimeter structure 204 via the lid attach material 236 (i.e., sitting on the lower surface of the recess 234 via the lid attach material 236) to provide an intermediate structure 252 (step 312), as illustrated in FIG. 4E. The lid 206 is parallel to the metalized laminate structure 202. The combination of the metalized laminate structure 202, the perimeter structure 204, and the lid 206 bonded to the perimeter structure 204 via the lid attach material 236 delimits the closed air cavity 214. As such, the wire-bond die 208 is positioned inside the air cavity 214. During this placing step, a curing procedure may be utilized to cure the lid attach material 236, and the curing procedure depends on the nature of the epoxy used for the lid attach material 236 (e.g., infrared curing, ultraviolet curing, heat curing, or the like).

The intermediate structure 252 is flipped upside down, where the flip-chip die 210 and the SMD 212 are attached to the second surface of the metalized laminate structure 202 (step 314), as illustrated in FIG. 4F. The flip-chip die 210 and the SMD 212 may be attached to the metalized laminate structure 202 via solder balls or solder paste. The flip-chip die 210 and the SMD 212 are positioned outside the air cavity 214 and each does not cover the second surface of the heat spreader 220 of the metalized laminate structure 202. Each of the flip-chip die 210 and the SMD 212 is electrically coupled to corresponding routing conductors 218 in the metalized laminate structure 202 (not shown). As such, the flip-chip die 210 and the SMD 212 are capable of communicating with each other, with the wire-bond die 208, and/or electrically/thermally connected with the interior conductive elements 224 (not shown). A reflow, AOI, and wash (step 316, not shown) is followed to clean any undesired solder ball/solder paste residue.

If the metalized laminate structure 202 includes one heat spreader 220, there is one thermal interposer 244 attached to the second surface of the heat spreader 220 via the interposer attach material 246 (step 318), as illustrated in FIG. 4G. The thermal interposer 244 is aligned with the heat spreader 220 and typically no smaller than the heat spreader 220 in the horizontal plane. The interposer attach material 246 is co-extensive with the thermal interposer 244 but does not have to be. Likewise, it is possible that the interposer attach material 246 spills past edges of the thermal interposer 244. However, a maximal heat transfer suggests that the thermal interposer 244 be at least as large as the interposer attach material 246. As illustrated, the heat generated by the wire-bond die 208 can be dissipated upward through the heat spreader 220 within the metalized laminate structure 202 and the thermal interposer 244.

After the flip-chip die 210, the SMD 212, and the thermal interposer 244 are attached, the top mold compound 242 is applied over the second surface of the metalized laminate structure 202 to provide a molded precursor 256 (step 320), as illustrated in FIG. 4H. Herein, the top mold compound 242 completely encapsulates the flip-chip die 210, the SMD 212, and the thermal interposer 244. The top mold compound 242 may be applied by sheet molding, overmolding, compression molding, transfer molding, and the like.

Typically, the thermal interposer 244 is taller than the flip chip die 210 and the SMD 212. The top mold compound 242 (at a top side of the molded precursor 256) is then thinned down to expose the thermal interposer 244 (step 322), as illustrated in FIG. 4I. In some cases, if the flip-chip die 210 generates a relatively large amount of heat and is taller than the SMD 212, the top mold compound 242 can be thinned down until both the backside of the thermal interposer 244 and the backside of the flip-chip die 210 are exposed. As such, the thermal interposer 244 and the flip-chip die 210 can be coupled to an external heat dissipating element (e.g., an external heat sink, not shown). This thinning step may be implemented by mechanical grinding.

In addition, a bottom side of the molded precursor 256 is also ground to be planarized (step 324), as illustrated in FIG. 4J. Herein, the lid 206 and the mold wall 222 are co-ground until each interior conductive element 224 is exposed through the mold wall 222. Herein, the lid 206 becomes thinner but still delimits the air cavity 214 with the perimeter structure 204 and the metalized laminate structure 202. Solder balls 232 IN are then applied at an exposed surface of each interior conductive element 224 (step 326), as illustrated in FIG. 4K. Next, the solder balls 232 IN reflow to provide the electrical contacts 232 (step 328) and complete the double-sided air-cavity package 200, as illustrated in FIG. 4L. Optionally the double-sided air-cavity package 200 may be laser marked (e.g., with a trademark, part number, or the like, step 330) and then singulated (step 332).

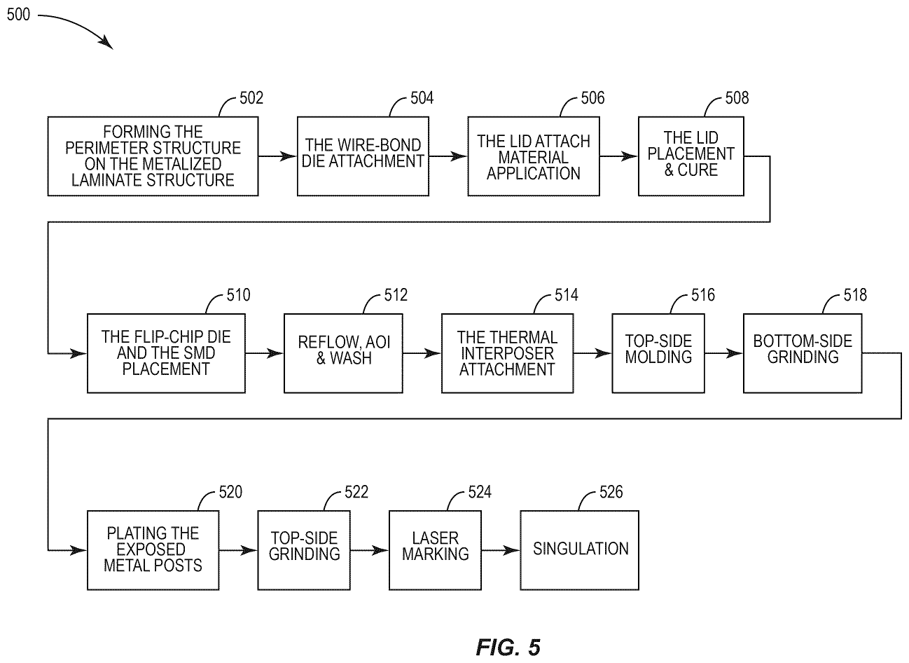

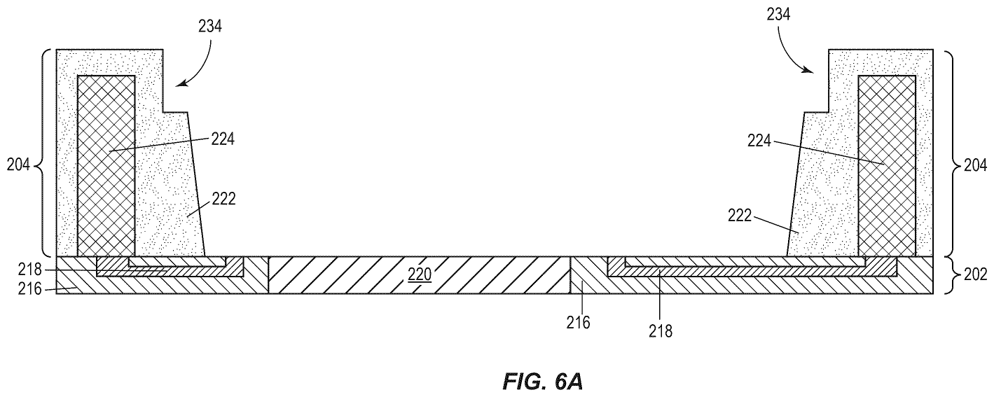

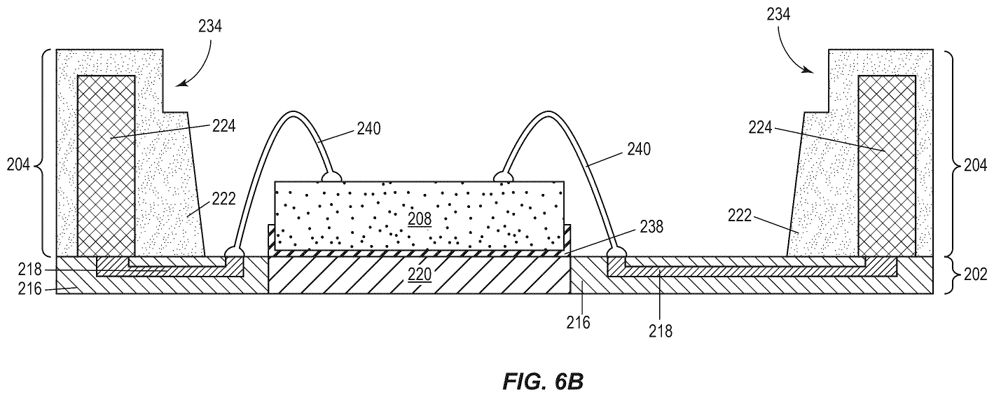

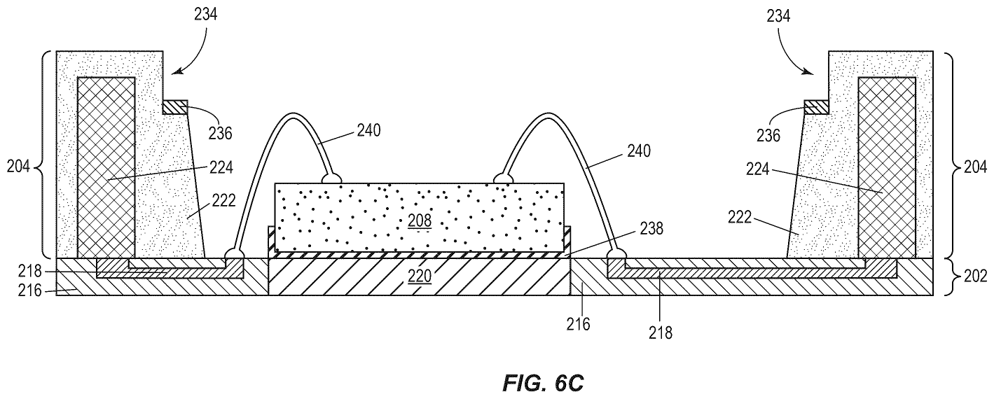

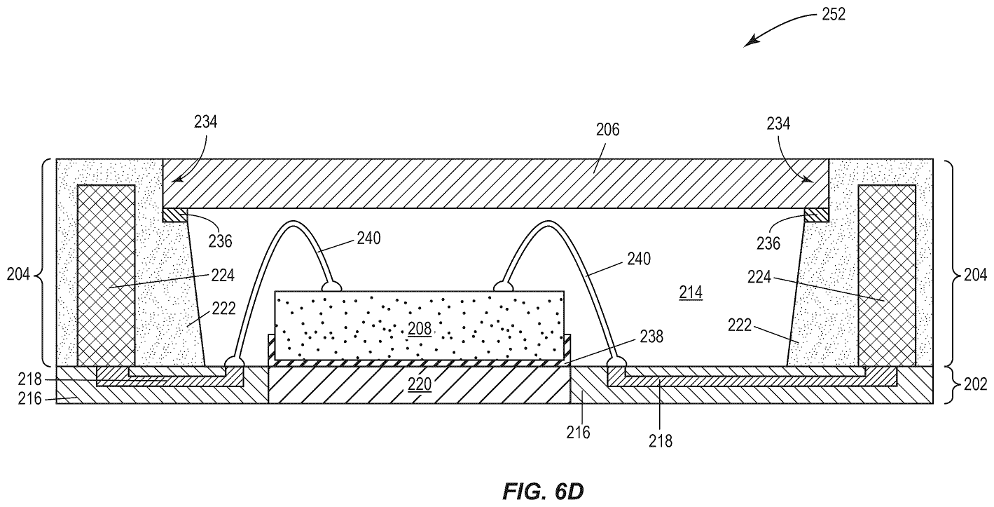

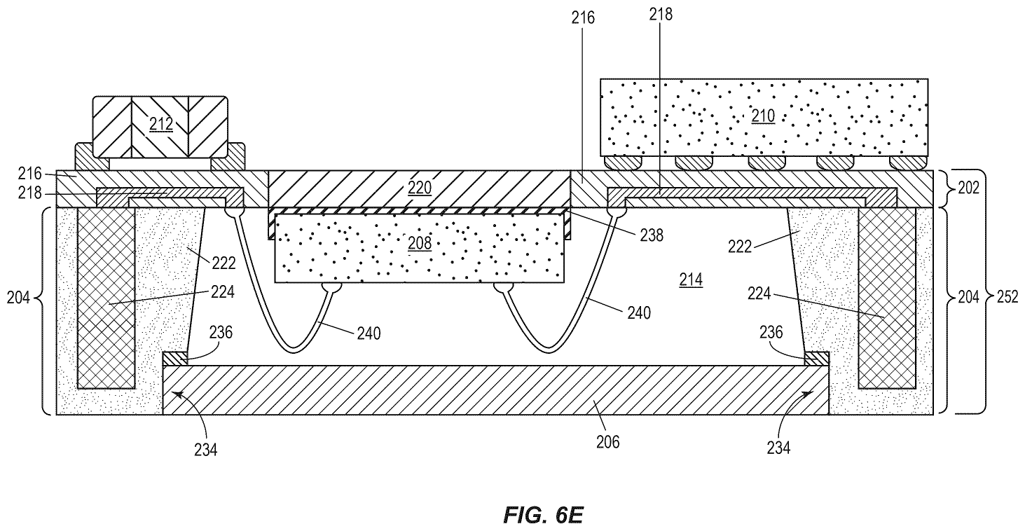

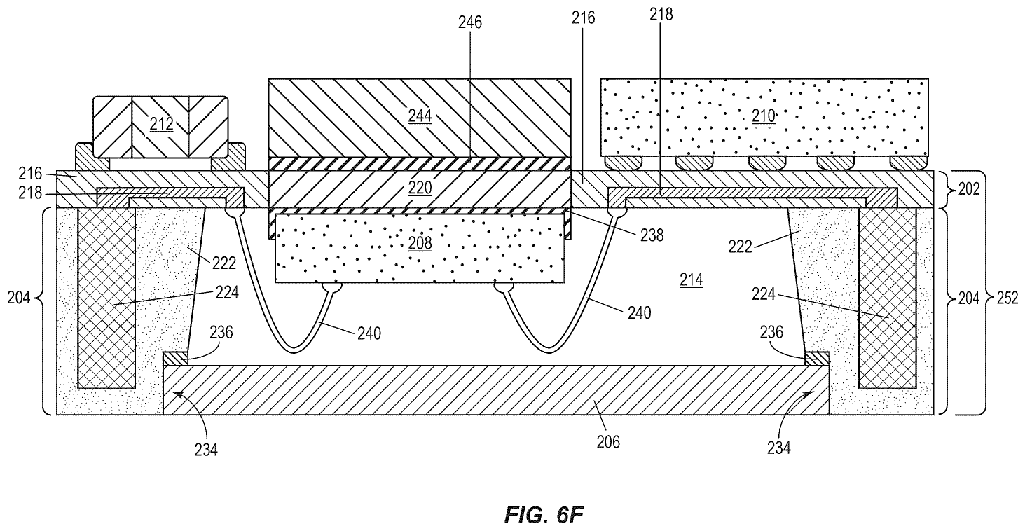

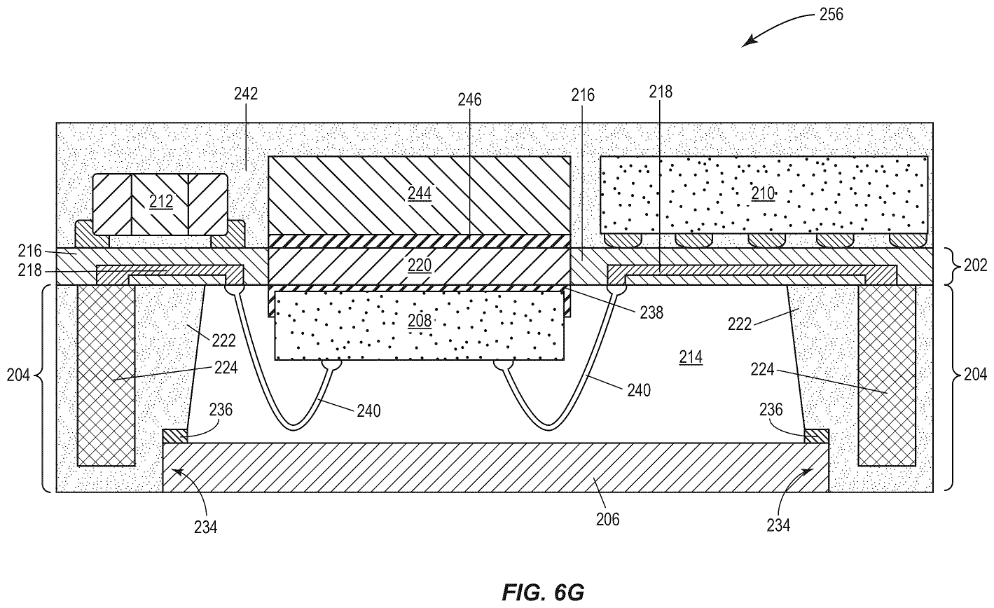

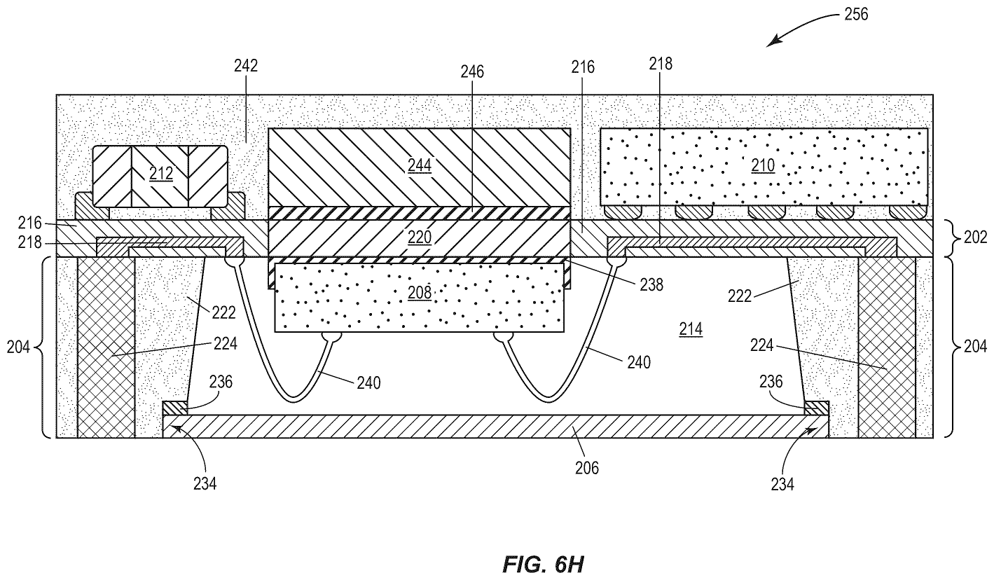

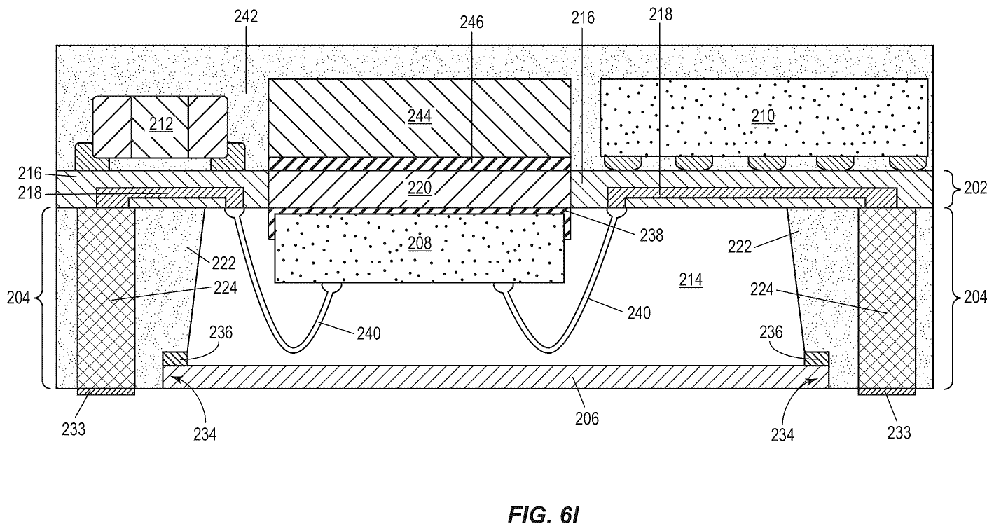

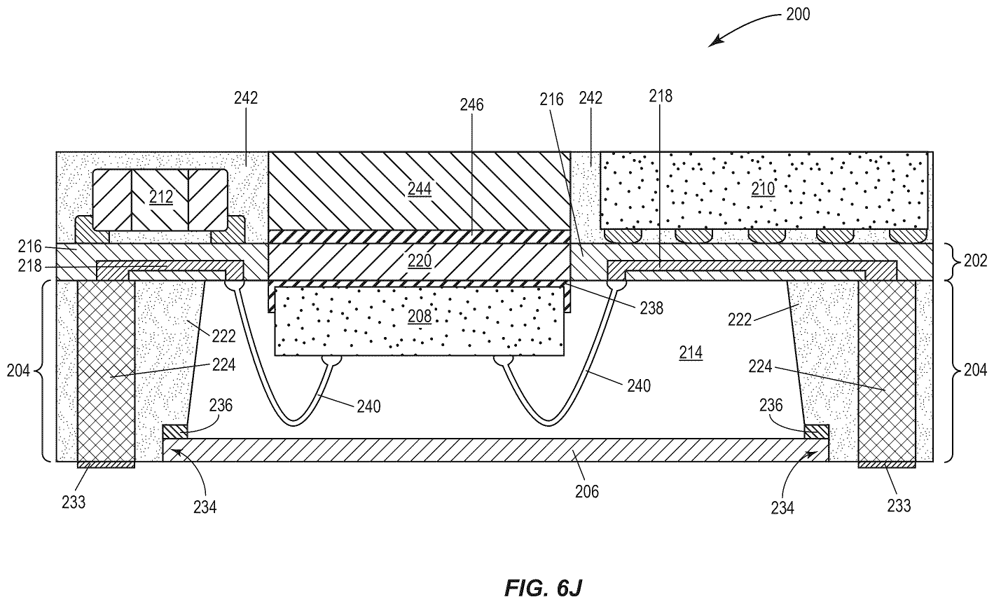

FIG. 5 provides another flow diagram that illustrates an alternative process 500 for fabricating the double-sided air-cavity package 200 shown in FIG. 2B according to some embodiments of the present disclosure. FIGS. 6A-6J illustrate the steps associated with the fabricating process 500 provided in FIG. 5. Although the flow diagram and the associated steps are illustrated in a series, they are not necessarily order dependent. Some steps may be done in a different order than that presented. Further, processes within the scope of this disclosure may include fewer or more steps than those illustrated in FIG. 5 and FIGS. 6A-6J.

In this regard, the process 500 starts with forming the perimeter structure 204 on the first surface of the metalized laminate structure 202 at the periphery of the metalized laminate structure 202 (step 502), as illustrated in FIG. 6A. For the purpose of this illustration, the metalized laminate structure 202 includes one heat spreader 220, which extends vertically through the laminate body 216 and is surrounded by the perimeter structure 204 (i.e., the heat spreader 220 does not extend horizontally underneath any portion of the perimeter structure 204). In different applications, the metalized laminate structure 202 may include more heat spreaders extending vertically through the laminate body 216 and surrounded by the perimeter structure 204. Herein, the perimeter structure 204 includes the mold wall 222 and multiple metal posts 224.

The mold wall 222 is formed at the periphery of the metalized laminate structure 202 without covering a center portion of the first surface of the metalized laminate structure 202 (i.e., the first surface of the heat spreader 220 is completely exposed through the mold wall 222). Each metal post 224 resides inside the mold wall 222 and is electrically and thermally connected to a corresponding routing conductor 218 within the metalized laminate structure 202. In addition, the mold wall 222 is formed to include the recess 234 (also referred to as a shoulder or lip) at an upper internal side of the mold wall 222. Note that the “lower” and “upper” location references are interchangeable, as intermediate structure(s) may be flipped upside down during the fabrication process. Herein, the mold wall 222 of the perimeter structure 204 may be formed by a selective molding process.

Steps 504-516 in the processing 500 are similar to the steps 308-320 in the processing 300. The wire-bond die 208 is attached to the first surface of the heat spreader 220 of the metalized laminate structure 202 via the die attach material 238 (step 504), as illustrated in FIG. 6B. As such, the heat generated by the wire-bond die 208 can be dissipated through the heat spreader 220 of the metalized laminate structure 202. The wire bonds 240 of the wire-bond die 208 are coupled to the certain ones of the routing conductors 218 of the metalized laminate structure 202, such that electrical signals as well as the heat generated by the wire-bond die 208 can be transmitted through the wire bonds 240, the routing conductors 218, and the interior conductive elements 224 connected to the routing conductors 218.

The lid attach material 236 (e.g., epoxy) is dispended at the lower surface of the recess 234 (step 506), as illustrated in FIG. 6C. The lid 206 is then placed into the perimeter structure 204 via the lid attach material 236 (i.e., sitting on the lower surface of the recess 234 via the lid attach material 236) to provide an intermediate structure 252 (step 508), as illustrated in FIG. 6D. The combination of the metalized laminate structure 202, the perimeter structure 204, and the lid 206 bonded to the perimeter structure 204 via the lid attach material 236 delimits the closed air cavity 214. As such, the wire-bond die 208 is positioned inside the air cavity 214.

The intermediate structure 252 is flipped upside down, where the flip-chip die 210 and the SMD 212 are attached to the second surface of the metalized laminate structure 202 (step 510), as illustrated in FIG. 6E. The flip-chip die 210 and the SMD 212 may be attached to the metalized laminate structure 202 via solder balls or solder paste. The flip-chip die 210 and the SMD 212 are positioned outside the air cavity 214 and each does not cover the second surface of the heat spreader 220 of the metalized laminate structure 202. Each of the flip-chip die 210 and the SMD 212 is electrically coupled to corresponding routing conductors 218 in the metalized laminate structure 202 (not shown). As such, the flip-chip die 210 and the SMD 212 are capable of communicating with each other, with the wire-bond die 208, and/or electrically/thermally connected with the interior conductive elements 224 (not shown). A reflow, AOI, and wash (step 512, not shown) is followed to clean any undesired solder ball/solder paste residue.

The thermal interposer 244 is then attached to the second surface of the heat spreader 220 via the interposer attach material 246 (step 514), as illustrated in FIG. 6F. The thermal interposer 244 is aligned with the heat spreader 220 and is typically no smaller than the heat spreader 220 in the horizontal plane. As illustrated, the heat generated by the wire-bond die 208 can be dissipated upward through the heat spreader 220 within the metalized laminate structure 202 and the thermal interposer 244. After the flip-chip die 210, the SMD 212, and the thermal interposer 244 are attached, the top mold compound 242 is applied over the second surface of the metalized laminate structure 202 to provide a molded precursor 256 (step 516), as illustrated in FIG. 6G. Herein, the top mold compound 242 completely encapsulates the flip-chip die 210, the SMD 212, and the thermal interposer 244.

Next, a bottom side of the molded precursor 256 is ground to be planarized (step 518), as illustrated in FIG. 6H. Herein, the lid 206 and the mold wall 222 are co-ground until each metal post 224 is exposed through the mold wall 222. Herein, the lid 206 becomes thinner but still delimits the air cavity 214 with the perimeter structure 204 and the metalized laminate structure 202. An exposed surface of each metal post 224 is plated (step 520), as illustrated in FIG. 6I. The plating step may be implemented by electroless nickel immersion gold (ENIG) plating or electroless nickel electroless palladium immersion gold (ENEPIG) plating and provides the plating section 233.

In addition, the top mold compound 242 at a top side of the molded precursor 256 is also thinned down to expose the backside of the thermal interposer 244 and the backside of the flip-chip die 210 (step 522) and complete the double-sided air-cavity package 200, as illustrated in FIG. 6J. Typically, the SMD 212 is shorter than the thermal interposer 244 and the flip chip die 210, such that the SMD 212 is still fully encapsulated by the top mold compound 242. This thinning step may be implemented by mechanical grinding. Furthermore, optionally the double-sided air-cavity package 200 may be laser marked (e.g., with a trademark, part number, or the like, step 524) and then singulated (step 526).

The systems and methods for top side cooling of a double-sided air-cavity package, according to aspects disclosed herein, may be provided in or integrated into any high-power processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

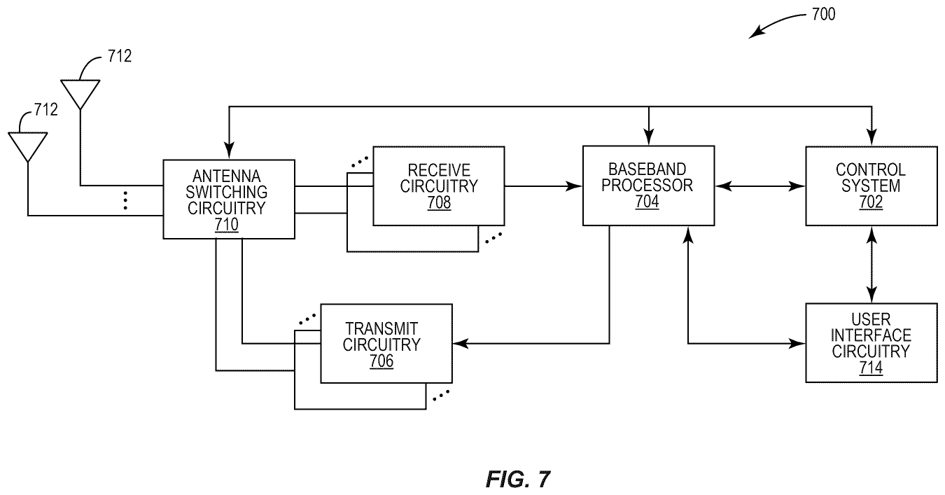

With reference to FIG. 7, the concepts described above may be implemented in various types of communication devices 700, such as those listed in the previous paragraph. The communication device 700 will generally include a control system 702, a baseband processor 704, transmit circuitry 706, receive circuitry 708, antenna switching circuitry 710, multiple antennas 712, and user interface circuitry 714. Herein, at least one or any combination of the control system 702, the baseband processor 704, the transmit circuitry 706, and the receive circuitry 708 may be implemented in the double-sided air-cavity package 200 (e.g. implemented in the wire-bond die 208 and/or the flip-chip die 210) described above.

In a non-limiting example, the control system 702 can be a field-

programmable gate array (FPGA) or an application-specific integrated circuit (ASIC), as an example. In this regard, the control system 702 can include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter of the receive circuitry 708 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 704 processes the digitized received signal to extract the information or data bits conveyed in the received signal. This processing typically comprises demodulation, decoding, and error correction operations, as will be discussed in greater detail below. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710. The multiple antennas 712 and the replicated transmit and receive circuitries 706, 708 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A double-sided air-cavity package comprising:
a metalized laminate structure including a heat spreader;
a perimeter structure that protrudes from a first surface of the metalized laminate structure and is positioned at a periphery of the metalized laminate structure without covering any portion of the heat spreader, wherein the perimeter structure includes at least one interior conductive element;
a lid positioned parallel to the metalized laminate structure and bonded to the perimeter structure, such that a combination of the metalized laminate structure, the perimeter structure, and the lid delimits a closed air cavity;
a first electronic component attached to the first surface of the metalized laminate structure proximate to the heat spreader and positioned within the air cavity, such that heat generated by the first electronic component is capable of being dissipated through the heat spreader in the metalized laminate structure, wherein the first electronic component is electrically connected to the at least one interior conductive element within the perimeter structure; and
a second electronic component attached to a second surface of the metalized laminate structure opposite the first surface of the metalized laminate structure, wherein the second electronic component is positioned outside the air cavity and does not reside over the heat spreader.

2. The double-sided air-cavity package of claim 1, wherein:
the metalized laminate structure further includes a laminate body and a plurality of routing conductors inside the laminate body;
the heat spreader is embedded in and extending vertically through the laminate body, such that a first surface of the heat spreader is a part of the first surface of the metalized laminate structure; and
the first electronic component is electrically connected to the at least one interior conductive element via certain ones of the plurality of routing conductors.

3. The double-sided air-cavity package of claim 2, wherein:
the first electronic component is a wire-bond die;
the first electronic component is attached to the first surface of the heat spreader via a die attach material; and
wire bonds of the first electronic component are coupled to the certain ones of the plurality of routing conductors in the metalized laminate structure.

4. The double-sided air-cavity package of claim 3 further comprising a top mold compound, wherein the top mold compound is applied to the second surface of the metalized laminate structure to at least partially encapsulate the second electronic component.

5. The double-sided air-cavity package of claim 4 further comprising a thermal interposer, wherein:
the thermal interposer is attached to a second surface of the heat spreader, opposite the first surface of the heat spreader, via an interposer attach material, wherein the second surface of the heat spreader is a part of the second surface of the metalized laminate structure; and
the thermal interposer extends vertically through the top mold compound, such that the heat generated by the first electronic component is capable of being dissipated through the heat spreader within the metalized laminate structure and the thermal interposer embedded in the top mold compound.

6. The double-sided air-cavity package of claim 1, wherein the second electronic component is a flip-chip die or a surface mounted device (SMD).

7. The double-sided air-cavity package of claim 1, wherein the lid is formed from FR4 or liquid crystal polymer (LCP).

8. The double-sided air-cavity package of claim 2, wherein:
the perimeter structure includes a mold wall and the at least one interior conductive element;
the mold wall protrudes from the first surface of the metalized laminate structure and is positioned at the periphery of the metalized laminate structure; and
the at least one interior conductive element is embedded in the mold wall and extends vertically through the mold wall, such that a top side and a bottom side of the at least one interior conductive element are not covered by the mold wall.

9. The double-sided air-cavity package of claim 8, wherein:
the mold wall is shaped to provide a recess, which is located at an internal side of the mold wall and vertically away from the metalized laminate structure, so as to accommodate the lid; and
the lid fits into the recess and is bonded to the mold wall via a lid attach material.

10. The double-sided air-cavity package of claim 8, wherein:
the at least one interior conductive element includes a plurality of interior conductive elements, each of which is a metal post; and
a top side and a bottom side of each of the plurality of interior conductive elements are not covered by the mold wall, wherein the top side of each of the interior conductive elements is electrically coupled to a corresponding one of the plurality of routing conductors in the metalized laminate structure.

11. The double-sided air-cavity package of claim 10 further comprising a plurality of plating sections, wherein:
each of the plurality of plating sections is directly formed underneath the bottom side of a corresponding one of the plurality of interior conductive elements; and
each of the plurality of plating sections comprises nickel, gold, and/or palladium.

12. The double-sided air-cavity package of claim 8, wherein:
the at least one interior conductive element is a stilted interconnect, which includes a dielectric region and multiple conductive pillars;
the dielectric region is formed of an insulating material or a semi-insulating material;
each of the conductive pillars extends vertically through the dielectric region, such that a top side and a bottom side of each of the conductive pillars are not covered by the dielectric region or the mold wall, and the top side of each of the conductive pillars is electrically coupled, via a solder paste, to a corresponding one of the plurality of routing conductors in the metalized laminate structure; and
each of the conductive pillars is composed of alternating plated vias and metal plates or alternating coined inserts and metal plates.

13. The double-sided air-cavity package of claim 12, wherein the at least one interior conductive element includes one continuous stilted interconnect having an open or closed ring frame shape.

14. The double-sided air-cavity package of claim 12, wherein the at least one interior conductive element includes a plurality of discrete stilted interconnects, each of which has a column shape.

15. The double-sided air-cavity package of claim 12 further comprising a plurality of electrical contacts, wherein:
each of the plurality of electrical contacts is directly formed underneath the bottom side of a corresponding one of the conductive pillars; and
the plurality of electrical contacts is formed from solder balls or solder paste.

16. A communication device comprising:
a control system;
a baseband processor;
receive circuitry; and
transmit circuitry, wherein at least one or any combination of the control system, the baseband processer, the transmit circuitry, and the receive circuitry is implemented in a double-sided air-cavity package, which includes a metalized laminate structure with a heat spreader, a perimeter structure, a lid, a first electronic component, and a second electronic component, wherein:
the perimeter structure, which includes at least one interior conductive element, protrudes from a first surface of the metalized laminate structure and is positioned at a periphery of the metalized laminate structure without covering any portion of the heat spreader;
the lid is positioned parallel to the metalized laminate structure and bonded to the perimeter structure, such that a combination of the metalized laminate structure, the perimeter structure, and the lid delimits a closed air cavity;
the first electronic component is attached to the first surface of the metalized laminate structure proximate to the heat spreader and positioned within the air cavity, such that heat generated by the first electronic component is capable of being dissipated through the heat spreader in the metalized laminate structure;
the first electronic component is electrically connected to the at least one interior conductive element within the perimeter structure; and
the second electronic component is attached to a second surface of the metalized laminate structure opposite the first surface of the metalized laminate structure, wherein the second electronic component is positioned outside the air cavity and does not reside over the heat spreader.

17. A method of fabricating a double-sided air-cavity package comprising:
forming a perimeter structure on a first surface of a metalized laminate structure, wherein:
the metalized laminate structure includes a heat spreader, and the perimeter structure includes a mold wall and at least one interior conductive element;
the mold wall protrudes from a periphery of the first surface of the metalized laminate structure without covering any portion of the heat spreader, and is shaped to provide a recess at an internal side and vertically away from the metalized laminate structure; and
the at least one interior conductive element is embedded in the mold wall;
attaching a first electronic component to the first surface of the metalized laminate structure proximate to the heat spreader; wherein the first electronic component is electrically connected to the at least one interior conductive element within the perimeter structure;
placing and bonding a lid to the recess of the mold wall to be parallel to the metalized laminate structure, such that a combination of the metalized laminate structure, the perimeter structure, and the lid delimits a closed air cavity, wherein the first electronic component is positioned within the air cavity; and
attaching a second electronic component to a second surface of the metalized laminate structure opposite the first surface of the metalized laminate structure, wherein the second electronic component is positioned outside the air cavity and does not reside over the heat spreader.

18. The method of claim 17, wherein:
the metalized laminate structure further includes a laminate body and a plurality of routing conductors inside the laminate body;
the heat spreader is embedded in and extending vertically through the laminate body, such that a first surface of the heat spreader is a part of the first surface of the metalized laminate structure; and
the first electronic component is electrically connected to the at least one interior conductive element via certain ones of the plurality of routing conductors.

19. The method of claim 18, wherein:
the first electronic component is a wire-bond die;
the first electronic component is attached to the first surface of the heat spreader via a die attach material; and
wire bonds of the first electronic component are coupled to the certain ones of the plurality of routing conductors in the metalized laminate structure.

20. The method of claim 18 further comprising:
attaching a thermal interposer to a second surface of the heat spreader opposite the first surface of the heat spreader, wherein the second surface of the heat spreader is a part of the second surface of the metalized laminate structure;
applying a top mold compound to the second surface of the metalized laminate structure to completely encapsulate the second electronic component and the thermal interposer; and
thinning down the top mold compound until a backside of the thermal interpose is exposed.

21. The method of claim 18, wherein the at least one interior conductive element includes a plurality of interior conductive elements, each of which is a metal post.

22. The method of claim 21 further comprising:
after placing and bonding the lid, co-grinding the perimeter structure and the lid until a second side of each of the plurality of interior conductive elements opposite the first side of each of the plurality of interior conductive elements is exposed though the mold wall; and
plating the exposed bottom side of each of the plurality of interior conductive elements by electroless nickel electroless palladium immersion gold (ENEPIG) plating or electroless nickel immersion gold (ENIG) plating.

23. The method of claim 18, wherein:
the at least one interior conductive element is a stilted interconnect, which includes a dielectric region and multiple conductive pillars;
the dielectric region is formed of an insulating material or a semi-insulating material;
each of the conductive pillars extends vertically through the dielectric region; and
each of the conductive pillars is composed of alternating plated vias and metal plates or alternating coined inserts and metal plates.

24. The method of claim 23, wherein forming the perimeter structure comprises:
attaching the at least one interior conductive element to the first surface of the metalized laminate structure, wherein a first side of each of the conductive pillars in the at least one interior conductive element is electrically coupled via a solder paste to a corresponding one of the plurality of routing conductors in the metalized laminate structure; and
selectively applying a first mold compound to the first surface of the metalized laminate structure to form the mold wall that completely encapsulates the at least one interior conductive element and to provide the perimeter structure.

25. The method of claim 24 further comprising:
after placing and bonding the lid, co-grinding the perimeter structure and the lid until a second side of each of the conductive pillars opposite the first side of each of the conductive pillars is exposed though the dielectric region and the mold wall;
applying a solder ball to the exposed second side of each of the conductive pillars; and
reflowing the solder ball to provide an electrical contact at the second side of each of the conductive pillars.
